(19) United States
(12) Patent Application Publication
(10) Pub. No.: US 2003/0031958 A1
(43) Pub. Date: Feb. 13, 2003

(54) Photosensitive composition and process for producing articles covered with a patterned film

(76) Inventors: Noboru Tohge, Osaka-shi (JP); Mitsuhiro Kawazu, Osaka-shi (JP); Koichiro Nakamura, Osaka-shi (JP); Hiroaki Yamamoto, Osaka-shi (JP)

Correspondence Address: WENDEROTH, LIND & PONACK, L.L.P., 2033 K STREET N. W., SUITE 800, WASHINGTON, DC, 20006-1021, US

(21) Appl. No.: 10/096,913

(22) Filed: Mar. 14, 2002

(30) Foreign Application Priority Data
Apr. 27, 2001 (JP) 2001-131003

(51) Int. Cl. G03F 7/26

(52) U.S. Cl. 430/325; 430/910; 430/270.1

(57) ABSTRACT

A process for producing articles covered with a patterned film which can be formed by a short time of exposure and has high development sensitivity after exposure and excellent pattern accuracy and a photosensitive composition. The process comprises applying the photosensitive composition to a substrate, exposing the coating film to light in a pattern-form to polymerize exposed portions of the coating film, dissolving and removing unexposed portions. The composition comprises a metal alkoxide, a β-diketone and acrylic acid or methacrylic acid.

### FIELD OF THE INVENTION

The present invention relates to a photosensitive composition and a process for producing articles covered with a patterned film. More specifically, it relates to a photosensitive composition comprising an organic metal compound having photosensitivity and to a process for producing articles covered with a patterned film by applying the photosensitive composition to a substrate, exposing the coating film to light and removing unexposed portions.

1. Prior Art

Heretofore, photosensitive materials for forming a patterned film have been developed and a large number of photosensitive materials have been proposed. In general, requirements for photosensitive materials are as follows: (1) high sensitivity to irradiation energy, (2) high resolution, that is, excellent pattern accuracy and processability, and (3) high adhesion to a substrate. It is known that photosensitive sol and gel materials are used as means of forming a metal oxide thin film pattern.

It is also known that a photosensitive metal alkoxide obtained by substituting a photosensitive ligand for the ligand of an alkoxide of a metal such as zirconium or aluminum is used as one of the photosensitive sol and gel materials to improve the photosensitivity of the metal alkoxide. Jpn. J. Appl. Phys. Vol. 33 (1994), pp. L1181 to L1184, Part 2, No. 8B, Aug. 15, 1994 reports the photocurability of zirconium butoxide chelated by acetylacetone and a collection of polymer theses, Vol. 53, No. 4 pp. 253 to 259, April, 1996 reports the photosensitivity of aluminum-sec-butoxide modified by various β-diketones. Further, Applied Optics, Vol. 39, No. 4, pp. 489 to 493 and JP-A 2000-321415 (the term “JP-A” as used herein means an “unexamined published Japanese patent application”) disclose that a diffraction grating is produced by applying a photosensitive liquid composition comprising a metal alkoxide and a β-diketone to a substrate, exposing it to interference light to polymerize exposed portions of the coating film and dissolving (leaching) and removing unexposed portions. Further, JP-A 2000-322777 discloses that a metal oxide layer having a fine uneven portion is formed by applying a photosensitive liquid composition comprising a metal alkoxide, a β-diketone and a sensitizer (such as benzophenone) to a substrate, exposing the coating film to ultraviolet radiation through a photomask, developing and baking it.

However, since the exposure time to laser light required for curing these photosensitive materials (irradiation intensity of 10 mW/cm²) is long (10 to 30 minutes) and productivity is low, a photosensitive organic metal compound having higher sensitivity is desired. In the above Jβ-A 2000-322777 in which a sensitizer is used, the exposure time can be shortened but a large amount of the sensitizer is required, whereby the accuracy of the obtained patterned film tends to lower due to the great shrinkage of the film at the time of baking.

### SUMMARY OF THE INVENTION

It is an object of the present invention to provide a photosensitive composition for producing articles covered with a patterned film, which comprises a metal alkoxide as the main ingredient, can be formed into a film by a short time of exposure, has high sensitivity in development (dissolution and removal of unexposed portions) after exposure, excellent leaching properties (to such an extent that unexposed portions near the end of the patterned film are completely dissolved and removed) and excellent pattern accuracy.

It is another object of the present invention to provide a process for producing articles covered with a patterned film from the above photosensitive composition having excellent properties as described above.

Other objects and advantages of the present invention will become apparent from the following description.

According to the present invention, firstly, the above objects and advantages of the present invention are attained by a process for producing articles covered with a patterned film by applying a photosensitive composition to a substrate, exposing the coating film to light in a pattern-form to polymerize exposed portions of the coating film, and dissolving and removing unexposed portions, wherein the composition comprises a metal alkoxide, a β-diketone and acrylic acid or methacrylic acid.

According to the present invention, secondly, the above objects and advantages of the present invention are attained by a photosensitive composition comprising a metal alkoxide, a β-diketone and acrylic acid or methacrylic acid as the main ingredients.

### BRIEF DESCRIPTION OF THE DRAWINGS

FIG. 1 is a plan view (photomicrograph) of a patterned film obtained in Example 1 of the present invention; and

FIG. 2 is a plan view (photomicrograph) of a patterned film obtained in Comparative Example of the present invention.

### DETAILED DESCRIPTION OF THE PREFERRED EMBODIMENT

Preferred examples of the metal alkoxide contained in the photosensitive composition of the present invention include alkoxides of titanium, zirconium and aluminum. Out of these, titanium and zirconium tetraalkoxides and aluminum trialkoxide are more preferred. Examples of the above tetraalkoxides and aluminum trialkoxide include zirconium tetrapropoxide, zirconium tetrabutoxide, titanium tetraisopropoxide, titanium tetrabutoxide and aluminum tributoxide. Out of these, titanium tetrabutoxide is particularly preferred. The metal alkoxide is preferably contained in the photosensitive composition in an amount of 2 to 20 mol %.

In the present invention, a β-diketone which is a chelating agent for the metal alkoxide, and acrylic acid or methacrylic acid therewith are used. The β-diketone is a component which provides photosensitivity to the photosensitive composition. By using acrylic acid or methacrylic acid, the photosensitivity of the coating film is improved to shorten the exposure time and the unexposed portions after exposure can be accurately dissolved and removed to form a fine pattern. It is considered that acrylic acid or methacrylic acid reduces the size of colloidal particles contained in the photosensitive composition and a sol film formed after the application of the photosensitive composition.

Examples of the β-diketone include β-diketones having 5 to 13 carbon atoms such as acetylacetone, benzoylacetone, ethyl acetoacetate and dibenzoylmethane. Out of these, acetylacetone and benzoylacetone are preferred and benzoylacetone is particularly preferred.

Preferably, the contents of the acrylic acid or methacrylic acid and the β-diketone in the photosensitive composition satisfy the following expression in a molar ratio:

0.33≦(acrylic acid or methacrylic acid)/β-diketone≦6.

More preferably, they satisfy the following expression:

1.0≦(acrylic acid or methacrylic acid)/β-diketone≦3.

When the molar ratio of the acrylic acid or methacrylic acid to the β-diketone is lower than 0.33, the photosensitivity of a gel film does not improve compared with the case where only the β-diketone is coordinately bonded. When the molar ratio of the acrylic acid or methacrylic acid to the β-diketone is higher than 6, the film readily cracks. The β-diketone is preferably contained in the photosensitive composition in an amount of 1.0 to 20 mol %. The acrylic acid or methacrylic acid is preferably contained in the photosensitive composition in an amount of 1.0 to 20 mol %.

When the ratio of the total content of the β-diketone and acrylic acid or methacrylic acid to the content of the metal alkoxide in the above photosensitive composition is too high or too low, the photosensitivity of the photosensitive composition lowers. Therefore, the molar ratio of the total of the β-diketone and acrylic acid or methacrylic acid to the alkoxide is preferably 1:1 to 3:1, more preferably 1.5:1 to 2.5:1.

The photosensitive composition of the present invention generally contains an organic solvent. The organic solvent is selected according to the technique of forming a coating film. The coating technique is preferably casting, dip coating, gravure coating, flexographic printing or roll coating. Organic solvents used for casting and dip coating are preferably solvents having a high evaporation rate. If the evaporation rate of a solvent is too low, it takes time to dry a coating film, whereby the flowability of the coating solution becomes high and a uniform coating film may not be formed. Therefore, alcohol-based solvents having a high evaporating rate such as methanol, ethanol, isopropyl alcohol and tert-butoxy alcohol can be advantageously used. Organic solvents used for gravure coating, flexographic printing and roll coating are preferably solvents having a low evaporation rate. If the evaporation rate of a solvent is too high, the solvent evaporates before the coating solution is fully leveled, whereby a coating film having a poor appearance may be formed.

The evaporation rate of the solvent is generally evaluated by a relative evaporation rate index when the evaporate rate of butyl acetate is 100. Solvents having a value of 40 or less are classified as solvents having an extremely low evaporation rate and preferred as organic solvents used for gravure coating, flexographic printing and roll coating. The solvents include ethyl cellosolve, butyl cellosolve, cellosolve acetate, diethylene glycolmonoethyl ether, hexylene glycol, diethylene glycol, ethylene glycol, tripropylene glycol, diacetone alcohol and tetrahydrofurfuryl alcohol.

The above photosensitive composition used in the present invention preferably contains at least one of the above solvents. A plurality of the above solvents may be used in combination according to the coating technique and the characteristic properties of the coating solution. The content of the solvent in the photosensitive composition is preferably 40 to 94 mol %, more preferably 50 to 92 mol %.

Water is required to promote the hydrolysis and dehydration/condensation reaction of the metal alkoxide. Water is preferably added in an amount equal to or more than its stoichiometric amount required for hydrolysis. The content of water in the photosensitive composition is preferably 2 to 20 mol % including water contained in the solvent as an impurity. Since the above acrylic acid or methacrylic acid serves as a catalyst for the hydrolysis of the metal alkoxide, a catalyst does not need to be added.

The substrate used in the present invention is an optical part such as a lens, lens array or polarizer, or a plate-like body. Especially when an anti-reflection film is formed on a spherical or aspherical lens array, a material forming a lens is an UV or thermally curable resin having a high expansion coefficient in most cases. However, since the difference in thermal expansion coefficient between a dielectric film forming the anti-reflection film and this resin is generally large, the dielectric film may crack during a heat treatment in the film formation step, or adhesion between the film and the lens may be low. The photosensitive composition of the present invention can have improved adhesion to an optical element formed from an organic material such as a resin and can prevent cracking of the obtained film because it contains a metal alkoxide and β-diketone having an organic moiety in the molecule. By using a plate-like body as a substrate an optical element such as a diffraction grating or waveguide can also be produced and an anti-reflection film can be formed on the surface of the plate-like substrate.

In the present invention, exposure techniques such as photolithography and a laser double-beam interference exposure technique are advantageously used to expose the coating film. In addition, a laser drawing technique and other techniques may also be used.

In the present invention, when photolithography is used for exposure, the photosensitive composition is applied to a substrate, preferably a transparent substrate such as an optical part, to a wet thickness of 0.5 μm to 200 μm to form a coating film which is then dried. A pattern mask or photomask having a pattern consisting of light transmission areas of a predetermined shape and light screening areas of a predetermined shape is placed on the coating film and the coating film is exposed to ultraviolet radiation through the mask for 1 to 60 minutes to ensure that the light intensity at an exposed position should become 1 to 200 mW/cm² in order to polymerize exposed portions corresponding to the light transmission areas of the photomask of the coating film. This polymerization is carried out by the polymerization of the acryl group or methacryl group of acrylic acid or methacrylic acid contained in the coating film (by the ring opening of a C═C double bond) and the proceeding of a gelation reaction by the polymerization of a product obtained by the hydrolysis and dehydration/condensation of the metal alkoxide along with the decomposition of the chelate ring of the β-diketone. The unexposed portions corresponding to the light screening areas of the above photomask of the coating film are soluble in a solvent such as an alcohol because the polymerization of the acryl group or methacryl group and the gelation reaction do not proceed in the unexposed portions. A film having a thickness of 100 nm to 10 μm and a pattern corresponding to the light transmission area pattern of the above photomask is formed by leaching (dissolving and removing) the unexposed portions of the coating film with an alcohol or alkali aqueous solution. Thereafter, the patterned film is preferably further cured by heating at 80 to 350° C. for 5 minutes to 5 hours. It is considered that in this step of elevating the temperature up to 350° C. by heating, condensation polymerization takes place between a component insolubilized by the proceeding of the polymerization of the acryl group or methacryl group and a component formed by the disconnection of a chelate bond between the β-diketone and a metal (such as titanium). It is assumed that the polymerization product of the acrylic acid or methacrylic acid is gradually decomposed in the step of elevating the temperature up to 350° C. The film becomes fine due to an about 70% reduction in thickness from that before the heat treatment. By further increasing the temperature to 500° C. by heating to decompose and evaporate an organic substance contained in the film, a completely fine patterned film structure made from a metal oxide can be obtained.

When a laser double-beam interference exposure technique is used for exposure, the photosensitive composition is applied to a substrate or an optical part to a wet thickness of 0.5 μm to 200 μm to form a coating film which is then dried. The coating film is exposed to interference light by the laser double-beam interference exposure technique and then shadow portions (unexposed portions) of the interference pattern of the film are leached (dissolved and removed) with an alcohol or alkali aqueous solution to form a one-dimensional patterned film consisting of a large number of parallel linear projecting portions with a height of 100 nm to 10 μm corresponding to the exposed portions of the above interference pattern. After exposure to the above interference light, the film is rotated at, for example, 90° on the plane and exposed again to form exposed portions in a grid pattern and unexposed portions between the grid patterns of the film, whereby a two-dimensional pattern having a large number of fine hollow portions corresponding to the unexposed portions disposed regularly in a grid pattern can be formed by leaching. As for details of exposure to interference light, please refer to the above document (Applied Optics, Vol. 39, No. 4, pp. 489 to 493). The intensity of irradiation is adjusted to a low level so that the exposed portions of the vertical and horizontal lines of the lattice are dissolved in a solvent and joint portions (overlapped portions between vertical and horizontal lines) which are exposed twice are not dissolved in the solvent, thereby making it possible to form a two-dimensional pattern having a large number of fine columnar island-like projections corresponding to the twice-exposed portions disposed regularly in a grid pattern. The term “unexposed portions” as used in the present invention is defined as what include portions exposed weakly to such an extent that they dissolve in a solvent as described above. By changing the rotation angle of the film or by exposing three times while changing the rotation angle, the formed projecting or hollow portions of the two-dimensional pattern can be contolled to an arbitrary shape such as a rectangular or hexagonal shape.

A light source which is suitable for the sensitivity of the photosensitive composition is preferably used for exposure such as above. Preferred examples of the light source include mercury lamp, metal halide lamp, xenon lamp, excimer laser, YAG laser (third harmonic, fourth harmonic) and He—Gd laser.

### EXAMPLES

The following examples are given to further illustrate the present invention.

### Examples 1 to 4 and Comparative Examples 1 and 2

Titanium tetrabutoxide (Ti(OC₄H₉)₄, abbreviated as Ti(Obu)₄) as a starting material, benzoylacetone (C₆H₅COCH₂COCH₃, abbreviated as BzAcH) and methacrylic acid (CH₂═C(CH₃)COOH, abbreviated as MA) or acrylic acid (CH₂═CHCOOH, abbreviated as AA) as chemical modifiers and methanol (abbreviated as MeOH) as a solvent were used. In a clean room whose relative humidity was controlled to 20% or less, methacrylic acid or acrylic acid was added to titanium tetrabutoxide little by little and stirred to carry out a reaction, and further benzoylacetone was added and stirred for 30 minutes. Methanol or a mixture of methanol and water was further added and stirred until a uniform solution was obtained to prepare a coating solution. Titanium tetrabutoxide (Ti(Obu)₄), methacrylic acid (MA), acrylic acid (AA), benzoylacetone (BzAcH), methanol (MeOH) and water (H₂O) were used in amounts shown in Table 1 (in molar ratio) to prepare 6 different coating solutions

### (Examples 1 to 4 and Comparative Examples 1 and 2).

TABLE 1

| | Solution composition (molar ratio) | | | | | |
|---|---|---|---|---|---|---|
| | Ti(OBu)₄ | MA | AA | BzACH | MeOH | H₂O |
| Ex. 1 | 1.0 | 1.5 | 0 | 0.5 | 20 | 0.2 |
| Ex. 2 | 1.0 | 1.0 | 0 | 1.0 | 20 | 1.2 |
| Ex. 3 | 1.0 | 0.5 | 0 | 1.5 | 20 | 1.2 |
| Ex. 4 | 1.0 | 0 | 0.5 | 1.5 | 20 | 1.2 |
| C.Ex. 1 | 1.0 | 2.0 | 0 | 0 | 20 | 0.2 |
| C.Ex. 2 | 1.0 | 0 | 0 | 1.5 | 20 | 1.2 |

Ex. = Example
C.Ex. = Comparative Example

The above photosensitive compositions were each applied to one side of a 2 mm-thick 2.5 cm×2.5 cm quartz substrate by dip coating and dried at room temperature for 30 minutes, a photomask (measuring 2 cm×2 cm and having about 1,000 parallel ultraviolet light transmission band portions in strip with a width of 10 μm and a length of 2 cm at intervals of 10 μm (distance between the centers of 20 μm)) was then placed on the coating film, and the coating film was exposed to 10 mW/cm² of light from a high-pressure mercury lamp through the photomask to form a patterned film consisting of exposed portions and unexposed portions. Each of the quartz substrates having the exposed coating film was rinsed with ethanol to dissolve and remove the unexposed portions and further heated at 200° C. for 1 hour to complete the hydrolysis and dehydration/condensation polymerization of titanium tetrabutoxide and methacrylic acid or acrylic acid contained in the exposed film portions so as to obtain a patterned film adhered to the quartz substrate. When it was observed through SEM (scanning electron microscope), the obtained patterned film had a thickness shown in Table 2. The projecting portions of the film had a width of 10 μm, a height equal to the film thickness shown in Table 2 and a length of 2 cm and were disposed in parallel to one another at intervals of 10 μm (the projecting portions having distance between the centers of 20 μm). The exposure time (curing time) until the coating film was cured is shown in Table 2. The exposure time (curing time) is a value when the film thickness is 1.0 μm. In Examples 1 to 4, the portions unexposed to ultraviolet radiation were completely leached and high pattern resolution was obtained. These quartz substrates having the patterned film served as a diffraction grating. When the status of diffraction was observed using 632.8 nm beams oscillated from a He—Ne laser, primary diffracted light and secondary diffracted light were clearly observed. When they were also observed through SEM (scanning electron microscope), the residue of the unexposed portions was not observed at all in the quartz substrate between adjacent projecting portions of the diffraction grating. On the other hand, in Comparative Example 1, after 1 hour of a heat treatment at 200° C. as described above, the film cracked. In Comparative Example 2, the exposure time (curing time) until the coating film was cured was 10 minutes which is longer than the curing time (1 to 5 minutes) of Examples 1 to 4.

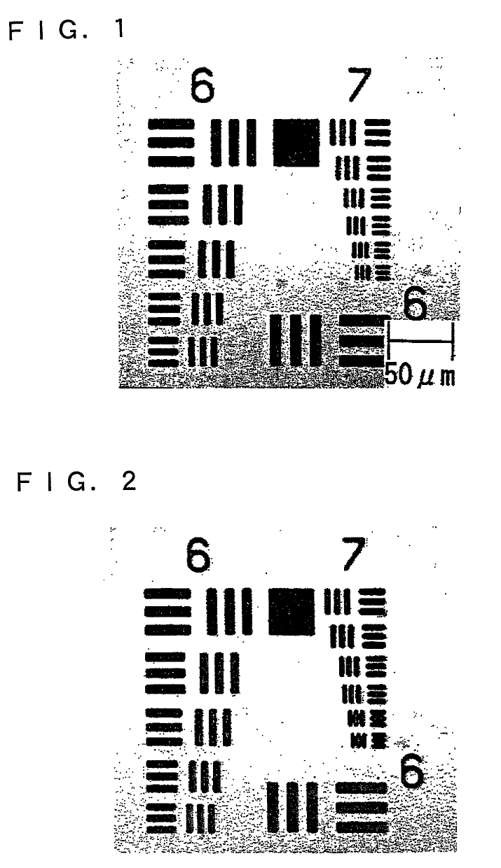

After the compositions used in Example 3 and Comparative Example 2 were applied to a silicon (Si) substrate, the obtained coating films were exposed to 10 mW/cm² of ultraviolet radiation from a high-pressure mercury lamp through a fine pattern mask for the inspection of resolution and leached with ethanol as a solvent. Photomicrographs of the gel films of the composition of Example 3 and the composition of Comparative Example 2 after leaching are shown in FIG. 1 and FIG. 2, respectively. In these figures, black portions are portions in the films which were exposed, polymerized and not dissolved, and bright portions are the surfaces of the silicon substrates. The smallest 2 μm pattern shown by three finest black lines in a slightly lower right part of the figure is clearly observed in the gel film of the composition of Example 3 shown in FIG. 1 whereas the resolution of the same pattern is low and a blurred image is observed in the gel film of the composition of Comparative Example 2 shown in FIG. 2.

TABLE 2

| | Film thickness (μm) | curing time |
|---|---|---|
| Ex. 1 | 0.4-0.7 | 1 minute |
| Ex. 2 | 0.5-1.0 | 2 minutes and 40 seconds |
| Ex. 3 | 0.8-1.1 | 5 minutes |
| Ex. 4 | 0.8-1.2 | 5 minutes |
| C.Ex. 1 | 0.1-0.2 | 1 minute |
| C.Ex. 2 | 0.8-1.3 | 10 minutes |

Ex. = Example
C.Ex. = Comparative Example

### Example 5

A microlens array board having 120 UV curable resin convex lenses which had a curvature radius of 100 μm and a substantially semicircular arc cross section and were disposed regularly on one side of a 0.5 mm-thick quartz substrate measuring 1.5 cm×2.5 cm was prepared. A photosensitive titanium alkoxide film having the same composition as in Example 1 was formed on both sides of this microlens array board to a thickness of about 200 nm by spin coating. The obtained coating film on both sides of the microlens array board was exposed to interference light having a cycle of about 0.5 μm of a He—Gd laser (325 nm) from the side opposite to the side having a lens array of the microlens array board by a double-beam interference exposure technique for 3 minutes. Further, this sample was rotated at 90° and subjected to double-beam interference exposure for 3 minutes again. After unexposed portions (shadow portions of an interference pattern and vertical and horizontal line portions of interference pattern light) of the films were dissolved and removed with ethanol, the coating films were developed and heated at 300° C. for 20 minutes. Thereby, an anti-reflection film having a two-dimensional cyclic structure that a large number of columnar island-like projections having a diameter of 200 nm and a height of about 200 nm corresponding to exposed portions (overlapped portions between the vertical and horizontal lines of interference pattern light) disposed in a grid pattern at intervals of 0.5 μm was formed on both sides of the microlens array board.

When the transmission of the obtained microlens array having an anti-reflection film on both sides was measured, the array had an average transmission of light having a wavelength of 1,000 to 2,000 nm of 97.5% or more. This value is larger than the average transmission (94%)of the microlens array board before the anti-reflection films were formed. Therefore, a lens array having excellent anti-reflection properties, that is, excellent transmission could be obtained. It was confirmed that even when this lens array was left at 85° C. and 85% RH for 500 hours, its anti-reflection properties did not deteriorate and the anti-reflection films firmly adhered to the microlens array board. A film was formed in the same manner as described above except that the interference light exposure time was changed from 3 minutes to 10 minutes. The film had a two-dimensional cyclic structure that columnar hollow portions having a diameter of 200 nm and a depth of about 200 nm were formed in the film having a thickness of about 200 nm in a grid pattern at intervals of 0.5 μm. When the transmission of this microlens array with the film was measured in the same manner as described above, the average transmission was 97.8%.

According to the present invention, there is obtained a finely patterned film which has higher sensitivity and shorter exposure time than conventional photosensitive sol and gel materials and has excellent accuracy and clear boundaries between exposed and unexposed portions by leaching the unexposed portions. There are also obtained an article covered with an anti-reflection patterned film which is excellent in terms of heat resistance, water resistance and chemical resistance and an article covered with a patterned film which is used as an optical element such as a diffraction grating or optical waveguide.

What is claimed is:

1. A process for producing articles covered with a patterned film, which comprises applying a photosensitive composition to a substrate, exposing the coating film to light in a pattern-form to polymerize exposed portions of the coating film, and dissolving and removing unexposed portions,
said photosensitive composition comprising a metal alkoxide, a β-diketone and acrylic acid or methacrylic acid.

2. The process of claim 1, wherein said photosensitive composition comprises acrylic acid or methacrylic acid in an amount of 0.33 to 6 mols based on 1 mol of said β-diketone.

3. The process of claim 1, wherein said photosensitive composition comprises acrylic acid or methacrylic acid in an amount of 1 to 3 mols based on 1 mol of said β-diketone.

4. The process of claim 1, wherein said photosensitive composition comprises said β-diketone and acrylic acid or methacrylic acid in a total amount of 1 to 3 mols based on 1 mol of said metal alkoxide.

5. The process of claim 1, wherein said metal alkoxide is titanium alkoxide and said β-diketone is benzoylacetone.

6. A photosensitive composition comprising a metal alkoxide, a β-diketone and acrylic acid or methacrylic acid as main ingredients.

7. The photosensitive composition of claim 6, wherein said metal alkoxide is an alkoxide of titanium, zirconium or aluminum.

8. The photosensitive composition of claim 6, wherein said metal alkoxide is a tetraalkoxide or trialkoxide of titanium or zirconium, or an aluminum trialkoxide.

9. The photosensitive composition of claim 6, wherein said metal alkoxide is titanium tetraisopropoxide or titanium tetrabutoxide.

10. The photosensitive composition of claim 6, wherein said β-diketone is benzoylacetone or acetylacetone.

11. The photosensitive composition of any one of claims 6 to 10, wherein said photosensitive composition comprises 2 to 20 mol % of a metal alkoxide, 1.0 to 20mol % of a β-diketone, 1.0 to 20 mol % of acrylic acid or methacrylic acid, 40 to 94 mol % of a solvent and 2 to 20 mol % of water, the molar ratio of acrylic acid or methacrylic acid to said β-diketone being 0.33 to 6, and the molar ratio of the total of said β-diketone and acrylic acid or methacrylic acid to said metal alkoxide being 1 to 3.
